(19) United States
(12) Patent Application Publication
(10) Pub. No.: US 2017/0148920 A1
(43) Pub. Date: May 25, 2017

(54) THIN FILM TRANSISTOR, FABRICATING METHOD THEREOF, AND DISPLAY DEVICE

(71) Applicant: BOE TECHNOLOGY GROUP CO., LTD., Beijing (CN)

(72) Inventors: HUI ZHANG, Beijing (CN); QIANGTAO WANG, Beijing (CN)

(21) Appl. No.: 15/108,461

(22) PCT Filed: Dec. 28, 2015
(86) PCT No.: PCT/CN2015/099231

§ 371 Date: Jun. 27, 2016

(30) Foreign Application Priority Data
Jul. 13, 2015 (CN) 201510409418.2

(51) Int. Cl. H01L 29/786; H01L 29/66; H01L 27/12; H01L 29/49

(52) U.S. Cl. CPC H01L 29/78648; H01L 29/4908; H01L 29/78672; H01L 29/6675; H01L 27/1214; H01L 29/78633

(57) ABSTRACT

A thin film transistor (TFT), a method for fabricating the TFT, and a display device are provided. The TFT comprises a first gate electrode and a second gate electrode; and an active layer located in between of the first gate electrode and the second gate electrode and being insulated from the first gate electrode and the second gate electrode; wherein the first gate electrode is connected with the second gate electrode through a via hole; and the first gate electrode is made of a light-shielding material for blocking light from irradiating on the active layer.

### CROSS-REFERENCES TO RELATED APPLICATIONS

This PCT patent application claims priority of Chinese Patent Application No. 201510409418.2, filed on Jul. 13, 2015, the entire content of which is incorporated by reference herein.

### FIELD OF THE INVENTION

The disclosed subject matter generally relates to the display technologies and, more particularly, relates to a thin-film-transistor (TFT), a related fabricating method thereof, and a display device containing the same.

### BACKGROUND

A thin-film-transistor (TFT) is a necessary control device in any liquid crystal display (LCD) device. A traditional TFT can include a gate electrode, an insulating layer above the gate electrode, an active layer located above the gate insulating layer, and a source electrode and a drain electrode that are located respectively on the opposite sides of the active layer.

Along with the development of display technologies, a TFT often has a dual-gate-electrode structure. The dual-gate-electrode TFT can include a first gate electrode, a first gate insulating layer that is located above the first gate electrode, an active layer that is located above the first gate insulating layer, a source electrode and a drain electrode that are located respectively on the opposite sides of the active layer, a second gate insulating layer that is located above the source electrode and the drain electrode, and a second gate electrode that is located above the second gate insulating layer.

However, comparing to the conventional single-gate-electrode TFT, the dual-gate-electrode TFT has a more complex fabricating process. For example, a first additional process, including vapor deposition, exposure, development, and etching processes, needs to be performed to form the second gate electrode. As another example, a second additional process, including evaporation, needs to be performed to form the second gate insulating layer. Therefore, the complexity and the production cost are greatly increased for fabricating the dual-gate-electrode TFT.

Accordingly, it is desirable to provide a TFT, a related display device, and a related fabricating method.

### BRIEF SUMMARY OF THE DISCLOSURE

In accordance with some embodiments of the disclosed subject matter, a TFT, a method for fabricating the TFT, and a related display device are provided. An aspect of the present disclosure provides a TFT. In some embodiments, the TFT comprises: a first gate electrode and a second gate electrode; and an active layer located in between of the first gate electrode and the second gate electrode and being insulated from the first gate electrode and the second gate electrode, wherein the first gate electrode is connected with the second gate electrode through a via hole; and the first gate electrode is made of a light-shielding material for blocking light from irradiating on the active layer.

In some embodiments, the active layer is a low-temperature polysilicon material active layer.

In some embodiments, the first gate electrode comprises a portion that is extended beyond the active layer; the portion of the first gate electrode is connected with the second gate electrode through the via hole.

In some embodiments, the first gate electrode and the second gate electrode are made by a same material.

In some embodiments, the first gate electrode comprises a metal layer comprising a single metal element selected from a group of chromium (Cr), aluminum (Al), copper (Cu), titanium (Ti), tantalum (Ta), and molybdenum (Mo).

In some embodiments, the first gate electrode is an alloy layer comprising at least two metal elements selected from a group of chromium (Cr), aluminum (Al), copper (Cu), titanium (Ti), tantalum (Ta), and molybdenum (Mo).

In some embodiments, the TFT further comprises a buffer layer located on the first gate electrode; and a gate insulating layer located on the active layer; wherein the via hole penetrates the buffer layer and the gate insulating layer.

In some embodiments, the TFT further comprises a source electrode and a drain electrode that are both connected with the active layer.

Another aspect of the present disclosure includes a method for fabricating a TFT. In some embodiments, the method comprising: forming a first electrode on a base substrate, wherein the first gate electrode is made of a light-shielding material for blocking light from irradiating on the active layer; forming an active layer on the first electrode layer; and forming a second gate electrode layer, wherein the second gate electrode is connected with the first gate electrode through a via hole.

In some embodiments, the active layer is formed by using a low-temperature polysilicon material.

In some embodiments, the first gate electrode is formed larger than the active layer, and a portion of the first gate electrode that extends beyond the active layer is connected with the second gate electrode through the via hole.

In some embodiments, the first gate electrode and the second gate electrode are formed by a same material.

In some embodiments, forming the first gate electrode comprises forming a metal layer comprising a single metal element selected from a group of chromium (Cr), aluminum (Al), copper (Cu), titanium (Ti), tantalum (Ta), and molybdenum (Mo).

The method for fabricating the TFT of claim 11, wherein forming the first gate electrode comprises forming an alloy layer comprising at least two metal elements selected from a group of chromium (Cr), aluminum (Al), copper (Cu), titanium (Ti), tantalum (Ta), and molybdenum (Mo).

In some embodiments, the method further comprises: forming a buffer layer on the first gate electrode; and forming a gate insulating layer on the active layer.

In some embodiments, the method further comprises forming the via hole penetrates the buffer layer and the gate insulating layer in a direction perpendicular to a surface of the base substrate, wherein the second gate electrode is connected with the first gate electrode through the via hole.

In some embodiments, the method further comprises forming a source electrode and a drain electrode on opposite sides of the active layer respectively, wherein the source electrode and the drain electrode are both connected with the active layer.

Another aspect of the present disclosure provides a TFT array substrate, incorporating an disclosed TFT.

In some embodiments, the TFT array substrate comprises a driving area and a displaying area, the driving area comprises the TFT.

Another aspect of the present disclosure provides a display device, incorporating an disclosed TFT array substrate.

Other aspects of the present disclosure can be understood by those skilled in the art in light of the description, the claims, and the drawings of the present disclosure.

### BRIEF DESCRIPTION OF THE DRAWINGS

Various objects, features, and advantages of the disclosed subject matter can be more fully appreciated with reference to the following detailed description of the disclosed subject matter when considered in connection with the following drawings, in which like reference numerals identify like elements. It should be noted that the following drawings are merely examples for illustrative purposes according to various disclosed embodiments and are not intended to limit the scope of the present disclosure.

FIG. 1 is a schematic structural diagram of an exemplary TFT in a sectional view of a first direction in accordance with some embodiments of the disclosed subject matter;

FIG. 2 is a schematic structural diagram of the exemplary TFT in a sectional view of a second direction in accordance with some embodiments of the disclosed subject matter;

FIG. 3 shows an exemplary method for fabricating a first exemplary TFT in accordance with some embodiments of the disclosed subject matter; and

FIG. 4 shows an exemplary method for fabricating a second exemplary TFT in accordance with some embodiments of the disclosed subject matter.

### DETAILED DESCRIPTION

For those skilled in the art to better understand the technical solution of the disclosed subject matter, reference will now be made in detail to exemplary embodiments of the disclosed subject matter, which are illustrated in the accompanying drawings. Wherever possible, the same reference numbers will be used throughout the drawings to refer to the same or like parts.

In accordance with various embodiments, the disclosed subject matter provides a TFT, a method for fabricating the TFT, and a related display device.

In accordance with some embodiments of the disclosed subject matter, a TFT is provided. In some embodiments, the TFT can include: a base substrate, a first gate electrode, an active layer, and a second gate electrode. In some embodiments, the first gate electrode, the active layer, and the second gate electrode are formed sequentially in a direction perpendicular to a surface of the base substrate. The active layer is interposed between the first gate electrode and the second gate electrode. The first gate electrode and the second gate electrode are both insulated with the active layer. The first gate electrode is connected with the second electrode through a via hole. The first gate electrode is a metal light-shielding layer for blocking light from irradiating on the active layer. The active layer is a low-temperature polysilicon material.

A traditional low-temperature polysilicon TFT comprises a metal light-shielding layer and a second gate electrode. So based on the production process of the traditional low-temperature polysilicon TFT, the disclosed TFT that has a dual-gate-electrode structure can be formed by adding a simple step of generating a via hole. Comparing to the conventional production process of a dual-gate-electrode TFT, the disclosed method can reduce the complexity of production process, and save the production cost.

In addition, the TFT with a dual-gate-electrode structure can have an increased on-state current, which means an enhanced chargeability. A TFT with a double-gate-electrode structure can have a same on-state current with a smaller channel width compared to a single-gate-electrode TFT. A TFT with a smaller channel can have a reduced size. For a display device using Gate-Drive on Array (GOA) technique, using a reduced size TFT in the driving area can narrow the frame of the display device, while using a reduced size TFT in the displaying area can increase the aperture ratio of the display device.

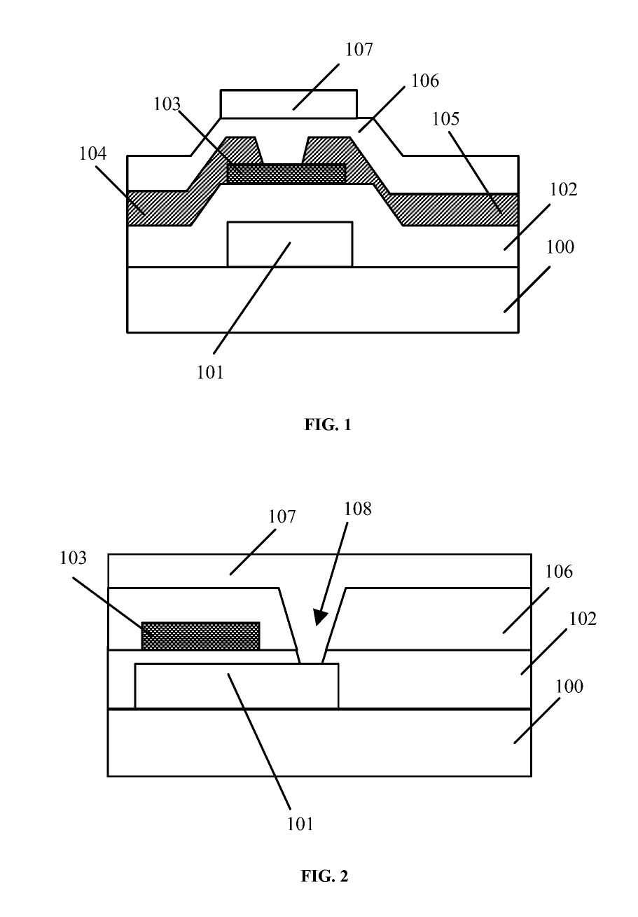

Turning to FIG. 1, a schematic structural diagram of an exemplary TFT in a sectional view of a first direction is shown in accordance with some embodiments of the disclosed subject matter.

As illustrated, the TFT can include: base substrate 100, first gate electrode 101, buffer layer 102, active layer 103, source electrode 104, drain electrode 105, insulating layer 106, second electrode 107, and a via hole.

In some embodiments, base substrate 100 can be any suitable substrate, such as a glass substrate, a transparent plastic substrate, and so on. First gate electrode 101 is a metal light-shielding layer located above base substrate 100. Buffer layer 102 is located above first gate electrode 101. Active layer 103 is a low-temperature polysilicon material located above buffer layer 102. Source electrode 104 and drain electrode 105 are located respectively on the opposite sides of active layer 103, and are both connected with active layer 103. Gate insulating layer 106 is located above source electrode 104 and drain electrode 105. The via hole penetrates gate insulating layer 106 and buffer layer 102. Second gate electrode 107 is located above gate insulating layer 106, and is connected with first electrode through 101 through the via hole.

Turning to FIG. 2, a schematic structural diagram of the exemplary TFT in a sectional view of a second direction is shown in accordance with some embodiments of the disclosed subject matter.

As illustrated, second gate electrode 107 is connected with first gate electrode 101 through via hole 108.

In some embodiments, first gate electrode 101 can include a first portion that is located directly below active layer 103 and a second portion that is extended out from the first portion. The second portion is connected with second gate electrode 107 through via hole 108.

In some embodiments, first gate electrode 101 and second gate electrode 107 can be made using the same material.

In some embodiments, first gate electrode 101 can be made by any suitable material that can not only ensure the light-shielding effect as a metal light-shielding layer, but also ensure the electrical properties as a first gate electrode. For example, first gate electrode 101 can be a metal layer that includes a single metal element, such as chromium (Cr), aluminum (Al), copper (Cu), titanium (Ti), tantalum (Ta), or molybdenum (Mo). As another example, first gate electrode 101 can be an alloy layer that comprises two or more metal elements of the following: Cr, Al, Cu, Ti, Ta, or Mo.

In some embodiments, buffer layer 102 and gate insulating layer 106 can be made of an silicon nitride (e.g., SiNx) or silicon oxide (e.g., SiO₂). Buffer layer 102 can be used for isolating first gate electrode 101 from active layer 103, which can avoid impurities diffusing into active layer 103 and affecting the performance of active layer 103.

In some embodiments, active layer 103 can be either P-type or N-type.

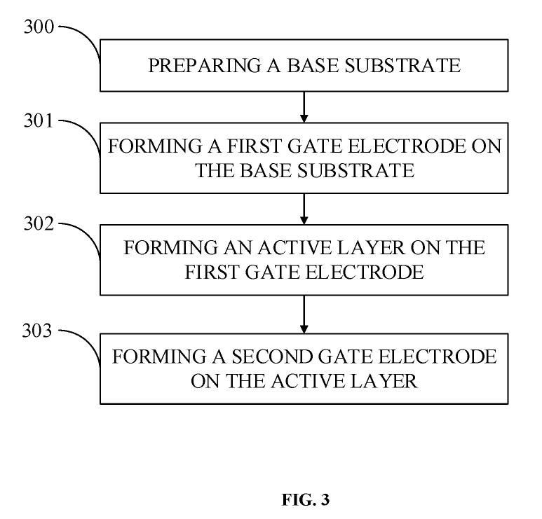

Turning to FIG. 3, an exemplary method for fabricating a first exemplary TFT is shown in accordance with some embodiments of the disclosed subject matter.

In some embodiments, the method can include:

Step 300: preparing a base substrate. The base substrate can be a glass substrate, a transparent plastic substrate, or any suitable substrate.

Step 301: forming a first gate electrode above the base substrate. The first gate electrode is a metal light-shielding layer.

Step 302: forming an active layer above the first gate electrode. The active layer is a low-temperature polysilicon material active layer.

Step 303: forming a second gate electrode above the active layer. The second gate electrode is connecting with the first gate electrode through a via hole which is in a direction perpendicular to a surface of the base substrate. The active layer is interposed between the first gate electrode and the second gate electrode. The first gate electrode and the second gate electrode are both insulated from the active layer.

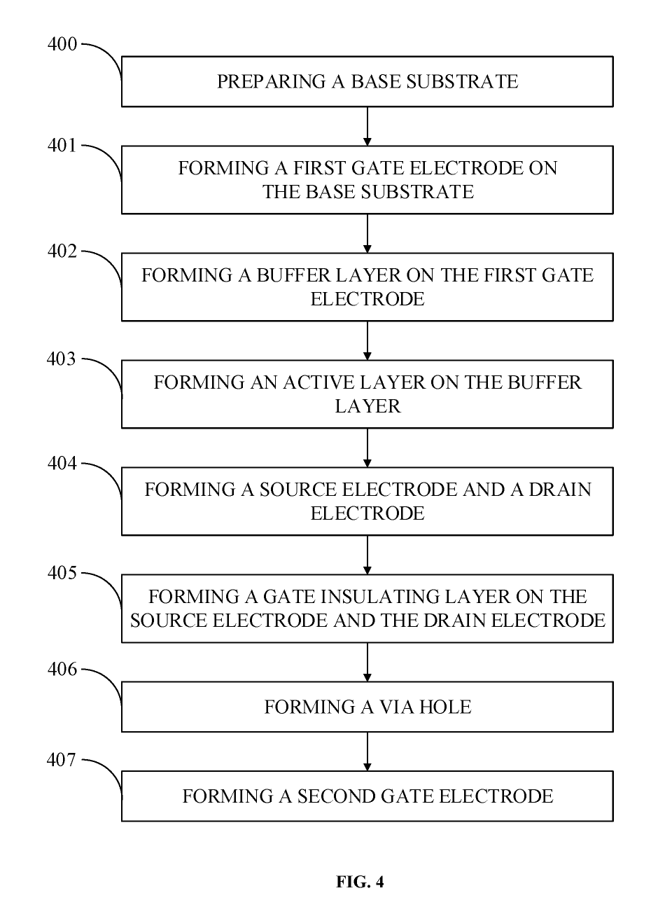

The specific fabricating processes of the first gate electrode, active layer, the second gate electrode, and the via hole will be describe below in connection with FIG. 4.

In some embodiments, the first gate electrode, the active layer, and the second gate electrode are formed sequentially in a direction perpendicular to the surface of the base substrate. The active layer is interposed between the first gate electrode and the second gate electrode. The first gate electrode and the second gate electrode are both insulated from the active layer. The first gate electrode is connected with the second electrode through a via hole. The first gate electrode is a metal light-shielding layer for blocking light from irradiating on the active layer. The active layer is a low-temperature polysilicon material.

A traditional low-temperature polysilicon TFT comprises a metal light-shielding layer and a second gate electrode. So based on the production process of the traditional low-temperature polysilicon TFT, the disclosed TFT that has a dual-gate-electrode structure can be formed by adding a simple step of generating a via hole. Comparing to the conventional production process of a dual-gate-electrode TFT, the disclosed method can reduce the complexity of production process, and save the production cost.

In addition, the TFT with a dual-gate-electrode structure can have an increased on-state current, which means an enhanced chargeability. It means that a TFT with a double-gate-electrode structure can have a same on-state current with a smaller channel width compared to a single-gate-electrode TFT. A TFT with a smaller channel can have a reduced size. For a display device using Gate-Drive on Array (GOA) technique, using a reduced size TFT in the driving area can narrow the frame of the display device, while using a reduced size TFT in the displaying area can increase the aperture ratio of the display device.

Turning to FIG. 4, an exemplary method for fabricating a second exemplary TFT is shown in accordance with some embodiments of the disclosed subject matter.

In some embodiments, the method can include:

Step 400: preparing a base substrate. The base substrate can be a glass substrate, a transparent plastic substrate, or any suitable substrate.

Step 401: forming a first gate electrode above the base substrate. First gate electrode 101 can be made by any suitable material that can not only ensure the light-shielding effect as a metal light-shielding layer, but also ensure the electrical properties as a first gate electrode. For example, first gate electrode 101 can be a metal layer that includes a single metal element, such as chromium (Cr), aluminum (Al), copper (Cu), titanium (Ti), tantalum (Ta), or molybdenum (Mo). As another example, first gate electrode 101 can be an alloy layer that comprises two or more metal elements of the following: Cr, Al, Cu, Ti, Ta, or Mo.

Step 402: forming a buffer layer above the first gate electrode. In some embodiments, the buffer layer can be made of an silicon nitride (e.g., SiNx) or silicon oxide (e.g., SiO₂).

Step 403: forming an active layer above the buffer layer. The active layer is a low-temperature polysilicon material active layer. The active layer can be either P-type or N-type.

In some embodiments, the active layer can be formed using any suitable method that can realize a low-temperature polysilicon material active layer. For example, the method can include: depositing an amorphous silicon thin film above the buffer layer; irradiating a high energy excimer laser onto the surface of the amorphous silicon film to melt the amorphous silicon; cooling the melted amorphous silicon to recrystallize, and obtaining low-temperature polycrystalline silicon thin film; etching the low-temperature polycrystalline silicon thin film to forming an active layer pattern; and doping the active layer with P-type or N-type dopant to obtain a P-type transistor or a N-type transistor.

In some embodiments, the deposition of the amorphous silicon thin film can use Plasma Enhanced Chemical Vapor Deposition (PECVD) method, Low Pressure Vapor Deposition (LPCVD) method, sputtering method, or any other suitable method.

The buffer layer formed in step 402 is used for isolating the first gate electrode from the active layer, which can avoid impurities diffusing into the active layer and affecting the performance of the active layer.

Step 404: forming a source electrode and a drain electrode. In some embodiments, the source electrode and the drain electrode can be formed on the opposite sides of the active layer respectively, and are both connected with the active layer. The source electrode and the drain electrode can be formed by ion implantation method.

Step 405: forming a gate insulating layer above the source electrode and the drain electrode.

Step 406: forming a via hole that penetrates the gate insulating layer and the buffer layer. The via hole can be formed by sequentially etching the gate insulating layer and the buffer layer using any suitable etching process.

Step 407: forming a second gate electrode above the gate insulating layer. The second gate electrode connects with the first gate electrode through the via hole.

In some embodiments, the first gate electrode can include a first portion that is located directly below the active layer and a second portion that is extended out from the first portion. The second portion is connected with the second gate electrode through the via hole.

In some embodiments, the first gate electrode and the second gate electrode can be made using the same material.

In some embodiments, the second gate electrode can be a metal layer that includes a single metal element, such as chromium (Cr), aluminum (Al), copper (Cu), titanium (Ti), tantalum (Ta), or molybdenum (Mo). In some embodiments, the second gate electrode can be an alloy layer that comprises two or more metal elements of the following: Cr, Al, Cu, Ti, Ta, or Mo.

In some embodiments, the structure of the first gate electrode, the buffer layer, the gate insulating layer and the second gate structure can be fabricated using conventional etching processes, which can include deposition, exposure, development, etching, and any other suitable steps.

In accordance with some embodiments of the disclosed subject matter, a TFT array substrate that comprises a TFT described above can be provided.

In some embodiments, the TFT array substrate can include a base substrate, a gate line, a data line, a pixel electrode layer and a TFT described above. A drain of the TFT is connected with the pixel electrode layer. One or more gate electrodes (e.g., a first gate electrode, and/or a second gate electrode) of the TFT are connected with the gate line. A source electrode of the TFT is connected with the data line.

In some embodiments, the pixel electrode layer can be a transparent conductive metal oxide layer, such as an Indium Tin Oxide (ITO) layer, an Indium Zinc Oxide (IZO) layer, or any other suitable metal oxide layer.

In some embodiments, the TFT array substrate can includes a driving area and a displaying area, wherein the driving area includes the TFT. Since the TFT has a dual-gate-electrode structure which can increase the on-state current, the TFT can have an enhanced chargeability. Comparing to a single-gate-electrode TFT, the described TFT with the double-gate-electrode structure can have a same on-state current with a smaller channel width, and thereby can have a reduced size. For a display device using Gate-Drive on Array (GOA) technique, using the reduced size TFT in the driving area can narrow the frame of the display device, while using the reduced size TFT in the displaying area can increase the aperture ratio of the display device.

In accordance with some embodiments of the disclosed subject matter, a display device that comprises a TFT array substrate described above can be provided. The display device can be any suitable device that has a display function, such as a mobile phone, a tablet computer, a television, a monitor, a notebook computer, a digital camera, a digital picture frame, a navigation system, etc.

The provision of the examples described herein (as well as clauses phrased as “such as,” “e.g.,” “including,” and the like) should not be interpreted as limiting the claimed subject matter to the specific examples; rather, the examples are intended to illustrate only some of many possible aspects.

Accordingly, a thin-film-transistor (TFT), a fabricating method of the TFT, and a related display device are provided.

Although the disclosed subject matter has been described and illustrated in the foregoing illustrative embodiments, it is understood that the present disclosure has been made only by way of example, and that numerous changes in the details of embodiment of the disclosed subject matter can be made without departing from the spirit and scope of the disclosed subject matter, which is only limited by the claims which follow. Features of the disclosed embodiments can be combined and rearranged in various ways. Without departing from the spirit and scope of the disclosed subject matter, modifications, equivalents, or improvements to the disclosed subject matter are understandable to those skilled in the art and are intended to be encompassed within the scope of the present disclosure.

1-20. (canceled)

21. A thin-film-transistor (TFT), comprising:
a first gate electrode and a second gate electrode; and
an active layer located in between of the first gate electrode and the second gate electrode and being insulated from the first gate electrode and the second gate electrode;
wherein the first gate electrode is connected with the second gate electrode through a via hole; and
the first gate electrode is made of a light-shielding material for blocking light from irradiating on the active layer.

22. The TFT of claim 21, wherein the active layer is a low-temperature polysilicon material active layer.

23. The TFT of claim 21, wherein:
the first gate electrode comprises a portion that is extended beyond the active layer; and
the portion of the first gate electrode is connected with the second gate electrode through the via hole.

24. The TFT of claim 21, wherein the first gate electrode and the second gate electrode are made by a same material.

25. The TFT of claim 21, wherein the first gate electrode comprises a metal layer comprising a single metal element selected from a group of chromium (Cr), aluminum (Al), copper (Cu), titanium (Ti), tantalum (Ta), and molybdenum (Mo).

26. The TFT of claim 21, wherein the first gate electrode is an alloy layer comprising at least two metal elements selected from a group of chromium (Cr), aluminum (Al), copper (Cu), titanium (Ti), tantalum (Ta), and molybdenum (Mo).

27. The TFT of claim 21, further comprising:
a buffer layer located on the first gate electrode; and
a gate insulating layer located on the active layer;
wherein the via hole penetrates the buffer layer and the gate insulating layer.

28. The TFT of claim 21, further comprising a source electrode and a drain electrode that are both connected with the active layer.

29. A method for fabricating a TFT, the method comprising:
forming a first electrode on a base substrate, wherein the first gate electrode is made of a light-shielding material for blocking light from irradiating on the active layer;
forming an active layer on the first electrode layer; and
forming a second gate electrode layer, wherein the second gate electrode is connected with the first gate electrode through a via hole.

30. The method for fabricating the TFT of claim 29, wherein the active layer is formed by using a low-temperature polysilicon material.

31. The method for fabricating the TFT of claim 29, wherein the first gate electrode is formed larger than the active layer, and a portion of the first gate electrode that extends beyond the active layer is connected with the second gate electrode through the via hole.

32. The method for fabricating the TFT of claim 29, wherein the first gate electrode and the second gate electrode are formed by a same material.

33. The method for fabricating the TFT of claim 32, wherein forming the first gate electrode comprises forming a metal layer comprising a single metal element selected from a group of chromium (Cr), aluminum (AI), copper (Cu), titanium (Ti), tantalum (Ta), and molybdenum (Mo).

34. The method for fabricating the TFT of claim 31, wherein forming the first gate electrode comprises forming an alloy layer comprising at least two metal elements selected from a group of chromium (Cr), aluminum (Al), copper (Cu), titanium (Ti), tantalum (Ta), and molybdenum (Mo).

35. The method for fabricating the TFT of claim 29, further comprising:
forming a buffer layer on the first gate electrode; and
forming a gate insulating layer on the active layer.

36. The method for fabricating the TFT of claim 29, further comprising forming the via hole penetrates the buffer layer and the gate insulating layer in a direction perpendicular to a surface of the base substrate, wherein the second gate electrode is connected with the first gate electrode through the via hole.

37. The method for fabricating the TFT of claim 29, further comprising forming a source electrode and a drain electrode on opposite sides of the active layer respectively, wherein the source electrode and the drain electrode are both connected with the active layer.

38. A TFT array substrate, comprising the TFT according to claim 21.

39. The TFT array substrate of claim 38, further comprising a driving area and a displaying area, wherein the driving area comprises the TFT.

40. A display device, comprising the TFT array substrate according to claim 39.
